(19) United States
(12) Patent Application Publication
(10) Pub. No.: US 2016/0344138 A1
(43) Pub. Date: Nov. 24, 2016

(54) LOCKABLE SMART PLUG

(71) Applicant: Kudoso Tech, LLC, Kalispell, MT (US)

(72) Inventor: Michael Steven Kazmier, Kalispell, MT (US)

(73) Assignee: Kudoso Tech, LLC, Kalispell, MT (US)

(21) Appl. No.: 15/157,665

(22) Filed: May 18, 2016

Related U.S. Application Data
(60) Provisional application No. 62/163,021, filed on May 18, 2015.

(51) Int. Cl. H01R 13/639; H01R 13/66; G01R 21/133; H01R 25/00

(52) U.S. Cl. CPC H01R 13/6395; H01R 25/006; H01R 13/6683; G01R 21/133

(57) ABSTRACT

The present invention is directed to a lockable, wireless (Wi-Fi or Bluetooth) enabled smart plug for monitoring and controlling usage of electronic devices. The smart plug of the present invention includes a housing unit, an electrical contact on a rear surface of the housing unit, an electrical receptacle on the surface opposite that of the electrical contact, and a cover configured to close over the electrical receptacle. Also included is a locking mechanism configured to secure the cover to the housing unit, a measuring device configured to monitor usage of the electrical receptacle, and a secure communication protocol to control the unit remotely.

### FIELD OF THE INVENTION

The present invention generally relates to a device for monitoring and controlling power to electronic devices. In particular, one embodiment of the present invention includes a secure, lockable, wireless (Wi-Fi or Bluetooth) enabled smart plug for monitoring and controlling usage of electronic devices.

### BACKGROUND OF THE INVENTION

There are a number of different smart plugs on the market today that control electrical power through the plug via software. However, a user cannot securely pair a smart plug with an electronic device to ensure control of that device; existing smart plugs do not provide locking mechanisms or secure attachments that prevent a power cord of a remote electronic device from being removed from the smart plug. For example, existing smart plugs allow a person to simply remove the power cord and place it in a standard, uncontrolled power receptacle. In addition, existing smart plugs are essentially open devices. That is, the existing smart plugs do not secure the communication between the controlling software and the plug. This, in turn, allows a multitude of devices and/or software to control the smart plug and ultimately control whether an electronic device receives power or not.

Accordingly, there remains a need for a smart plug that allows for a physically locked connection between the input power of the electronic device and the smart plug, while also securing the communication to ensure only authorized controlling devices and/or software may control the smart plug and the electronic device(s) paired with it.

### SUMMARY OF THE INVENTION

One embodiment of the present invention comprises a smart plug including a housing unit, at least one electrical contact on a rear surface of the housing unit, at least one electrical receptacle on a surface opposite that of the electrical contact, and a cover configured to close over the electrical receptacle. In this embodiment, the present invention also comprises a locking mechanism configured to secure the cover to the housing unit and a measuring device configured to monitor usage of, or the electric current associated with, the electrical receptacle. One embodiment of the cover includes at least one opening adapted to allow an electrical cord to egress the smart plug. The smart plug further includes a speaker located on the housing unit to provide an audible warning that the state of the device (power on/off) is going to change. In still another embodiment, the locking mechanism includes a tubular cam lock and in another embodiment the locking mechanism comprises an internal electromagnetic lock. In yet another embodiment, the smart plug includes two electrical receptacles that are independently monitored and controlled.

Another embodiment of the present invention includes current sensing metrology electronics connected to the wireless enabled smart plug controller for monitoring usage and identifying a remote electronic device plugged therein, including a housing unit, at least one electrical contact on a rear surface of the housing unit, and at least one electrical receptacle on the surface opposite that of the electrical contact. The embodiment further comprises a cover configured to close over at least one electrical receptacle, a locking mechanism configured to secure the cover to the housing unit, a measuring device configured to monitor usage of at least one electrical receptacle, and a controller configured to selectively control the on/off condition of the power to the at least one electrical receptacle and subsequently the remote electronic device plugged therein. In this aspect of the invention, the measuring device comprises an ammeter. In another embodiment, the cover includes dual members connected to opposing walls of the housing unit via a hinge that leaves an opening, e.g., a hole, large enough for the electrical cord to egress the cover but small enough that the electrical plug cannot egress.

Still another embodiment of the present invention includes the use of a locking band and wall divider to prevent a member that is inserted into an electrical receptacle from being removed. For example, the wireless (Wi-Fi or Bluetooth) enabled smart plug includes a housing unit, at least one electrical contact on a first surface of the housing unit, at least one electrical receptacle on a second surface of the housing unit, a locking band configured to extend over the at least one electrical receptacle and to operatively attach to each end of the housing unit, where the locking band includes at least one U-shaped opening, a wall divider positioned adjacent to the locking band and configured to enclose the at least one U-shaped opening, a processor operatively connected to the at least one electrical receptacle to monitor the usage of the at least one electrical receptacle, and a controller configured to selectively control the power status of the at least one electrical receptacle.

In this aspect, the at least one U-shaped opening may be positioned over the at least one electrical receptacle. In another embodiment, the smart plug includes two or more electrical receptacles. For instance, the processor may be operatively connected to the two or more electrical receptacles to monitor the usage of the two or more receptacles. In still another embodiment, the housing unit further includes a slot configured for insertion of the wall divider.

### BRIEF DESCRIPTION OF THE DRAWINGS

Further features and advantages of the invention can be ascertained from the following detailed description that is provided in connection with the drawing(s) described below:

FIG. 1 is a top view of a lockable smart plug according to one embodiment of the present invention;

FIG. 2 is a side view of a lockable smart plug according to another embodiment of the present invention;

FIG. 3 is a side view of a lockable smart plug according to still another embodiment of the present invention; and

FIG. 4 is a side view of a lockable smart plug according to yet another embodiment of the present invention;

FIG. 5A is a front view of a lockable smart plug according to one embodiment of the present invention;

FIG. 5B is a side view of the lockable smart plug depicted in FIG. 5A;

FIG. 5C is an alternate side view of the lockable smart plug depicted in FIG. 5A;

FIG. 6 is a top view of a lockable smart plug according to another embodiment of the present invention;

FIG. 7 is a top view of the housing unit of the smart plug according to one embodiment of the present invention; and

FIG. 8 is an exemplary block diagram of a controller in which processes involved in the embodiments described herein may be implemented.

### DETAILED DESCRIPTION OF THE PREFERRED EMBODIMENTS

One advantage of the lockable smart plug included in the present invention is that it allows an electronic device to be monitored and controlled like a “smart” device for the purpose of monitoring and controlling usage. In particular, one aspect of the present invention allows a user to monitor and control access to certain electronic devices plugged into the lockable smart plug based on variable authorization criteria. One embodiment of the lockable smart plug of the present invention securely holds the input power cord of the electronic device inside of the smart plug's housing, and prevents unauthorized users from tampering with, removing, or gaining access to the plug of the electronic device and subsequently ensures that the electronic device will only receive power when it is authorized to do so.

For instance, if a parent wishes to ensure that their child can only use a device, e.g., video game console, television, etc., for a limited period of time, the smart plug disclosed herein may be used. Alternately, if it is desirable to conserve power by cutting off power to a particular device during a predetermined time period, the present invention may be advantageous. Those skilled in the art will understand that the present invention may be used in a variety of situations including, but not limited to, situations where it is desirable to prevent tampering with, removing, or gaining access to the plug of an electronic device. Additionally, the present invention may also be used when it is desirable to control access to power, whether with regard to the current, voltage, or time period during which such power is accessible.

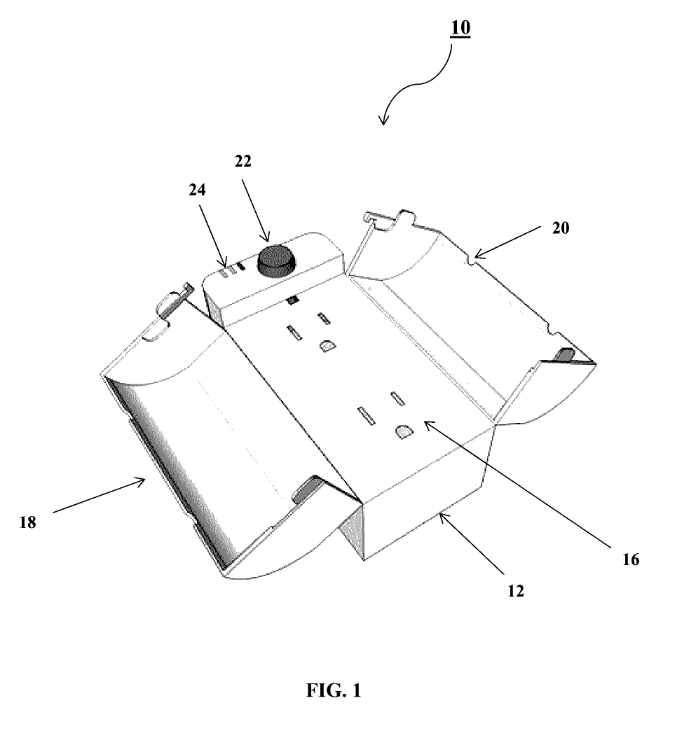

FIG. 1 illustrates one embodiment of a lockable smart plug 10 contemplated by the present invention. As shown in FIG. 1, the lockable smart plug 10 includes a housing unit 12. In one embodiment, the housing unit 12 may comprise a rectangular box. For example, the housing unit 12 may comprise a standard electrical outlet box. However, as will be apparent to those skilled in the art, the dimensions of the housing unit 12, e.g., the shape, size, etc., may be varied as desired by those skilled in the art.

The housing unit 12 includes at least one electrical contact 14 on a rear surface. The electrical contact 14 preferably provides power to the smart plug 10. In one embodiment, the electrical contact 14 comprises a standard male power connector. For example, the electrical contact 14 may comprise a standard male NEMA-5-15 AC power connector having three prongs: power, neutral, and ground. In another embodiment, the electrical contact 14 may be operably connected to a rear surface of a printed circuit board (PCB). In this aspect, a back shell may be fitted over the PCB to cover the rear surface of the PCB, while also allowing the prongs of the standard male power connector to extend through.

The housing unit 12 includes at least one electrical receptacle 16 on the surface opposite that of the electrical contact 14. For example, in one embodiment, the housing unit 12 includes at least two electrical receptacles 16 on the surface opposite that of the electrical contact 14. In another embodiment, the housing unit 12 includes at least three electrical receptacles 16 on the surface opposite that of the electrical contact 14. Alternately, the housing unit 12 may be expanded to include two electrical contacts 14 such that the housing unit 12 includes at least four electrical receptacles 16. In this aspect, the housing unit 12 includes at least two electrical receptacles 16 on each surface opposite that of the electrical contacts 14. The electrical receptacles 16 may be arranged in a vertical orientation or in a horizontal orientation.

In one embodiment, the at least one electrical receptacle 16 includes a standard female power receptacle. For example, the electrical receptacle 16 may include a standard female NEMA-5-15 power receptacle. The electrical receptacle 16 provides power to a remote electronic device that is monitored and controlled by the lockable smart plug 10. Specifically, the electrical receptacle 16 is designed for receipt of a plug contact associated with a remote electronic device. Examples of remote electronic devices include, but are not limited to, game consoles, Blu-ray players, DVD players, televisions, and computers. Each of these remote electronic devices includes an electrical cord and plug that can be received by an electrical receptacle 16 that is configured and dimensioned to receiving the plug.

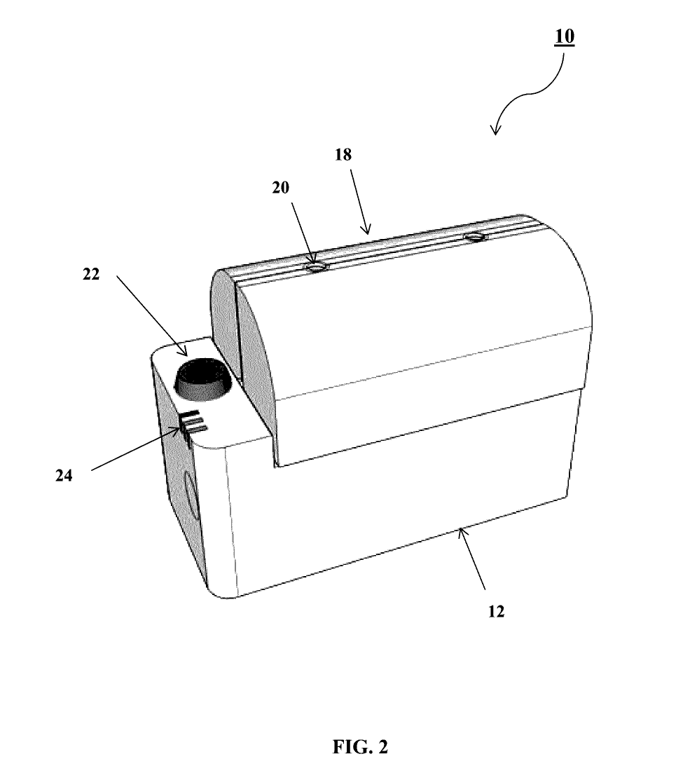

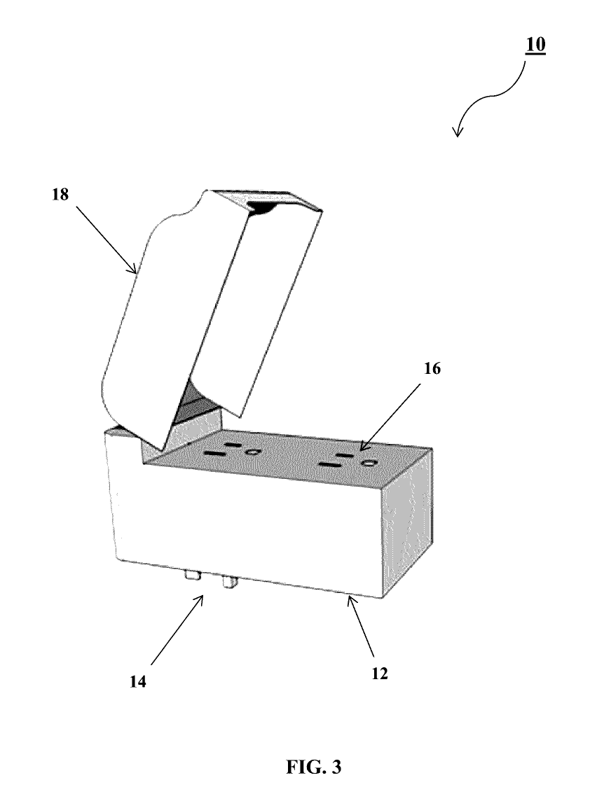

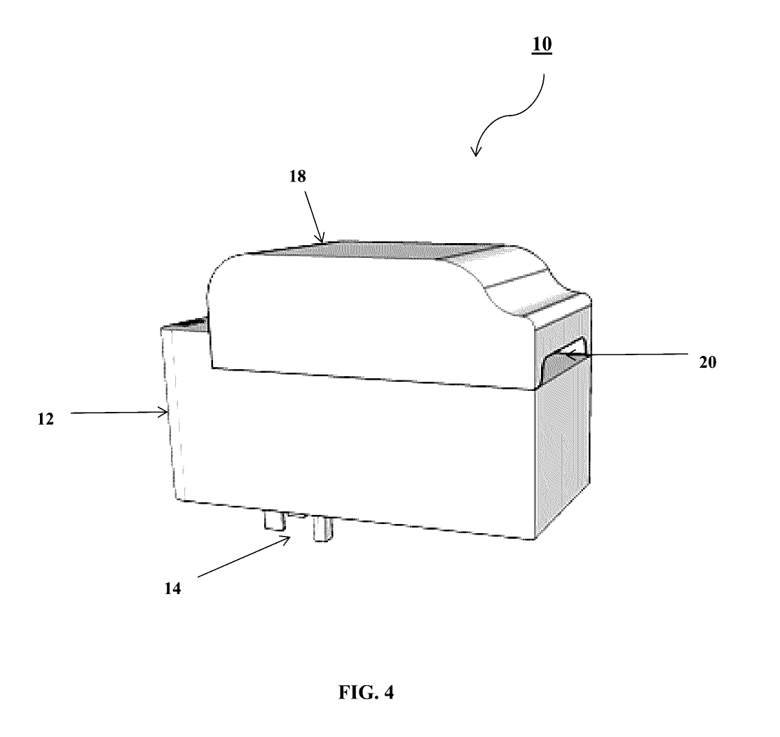

The lockable smart plug 10 also includes an apparatus that prevents a member that is inserted into at least one electrical receptacle 16 from being removed. The apparatus may preferably prevent the at least one electrical receptacle 16 from being accessed. This may be accomplished by a mechanical or electrical apparatus, or any other apparatus or method known to those skilled in the art. For example, the lockable smart plug 10 may include a cover 18 that is configured to open and close over the at least one electrical receptacle 16 located in the housing unit 12. In one embodiment, as shown in FIG. 1, the cover 18 comprises dual members that are operatively connected to the housing unit 12 on opposing walls. The dual members may be operatively connected to the housing unit 12 via a hinge. As shown in FIG. 2, the dual members may have interference surfaces that may be joined to form a closed cover 18 over the at least one electrical receptacle 16. In another embodiment, as shown in FIG. 3, the cover 18 includes a single member that is configured and dimensioned to be operatively connected to at least one wall of the housing unit 12. Similar to the dual member embodiment, the single member cover may be operatively connected to the housing unit 12 using, for example, a hinge. As shown in FIG. 4, the single cover 18 closes over the at least one electrical receptacle 16.

The cover 18 includes at least one opening 20 adapted to allow the electrical cord of the remote electronic device to egress the lockable smart plug 10 but to not allow the electrical plug of the remote electronic device to be removed. The size and shape of the opening 20 may be configured and dimensioned as desired; however, the dimensions of the opening 20 should be configured and dimensioned such that the plug of the remote electronic device is prevented from passing through the opening 20 after it has been closed and secured, although the electrical cord of the remote electronic device is allowed to egress from the smart plug 10. The opening 20 may vary as desired, and may be configured and dimensioned based on the type of plug with which it is intended to be used. For example, the opening may have a diameter of between about ¼ inch and about ½ inch. Alternately, an opening with a diameter greater than ½ inch may allow NEMA-1 (2-prong) AC Plugs to egress.

In one embodiment, the cover 18 includes at least one opening 20 for each electrical receptacle 16. For example, the cover 18 includes an opening 20 that allows a plug to access each electrical receptacle 16. In one embodiment, one or more openings 20 may be positioned above each electrical receptacle 16. In this aspect, when a single member cover is used, the opening 20 may be constructed entirely in the cover. However, when a dual member cover is used as shown in FIG. 1, the opening 20 may be configured such that each member of the cover 18 includes half of the opening 20. When the dual member cover is closed (as depicted in FIG. 2), each half of the opening may form the full opening 20.

In another embodiment, the cover 18 includes one opening 20 for multiple electrical receptacles 16. For example, as shown in FIGS. 3 and 4, the cover 18 includes a rectangular opening 20 at an end of the cover 18 to allow multiple electrical cords of multiple remote electronic devices to egress the lockable smart plug 10.

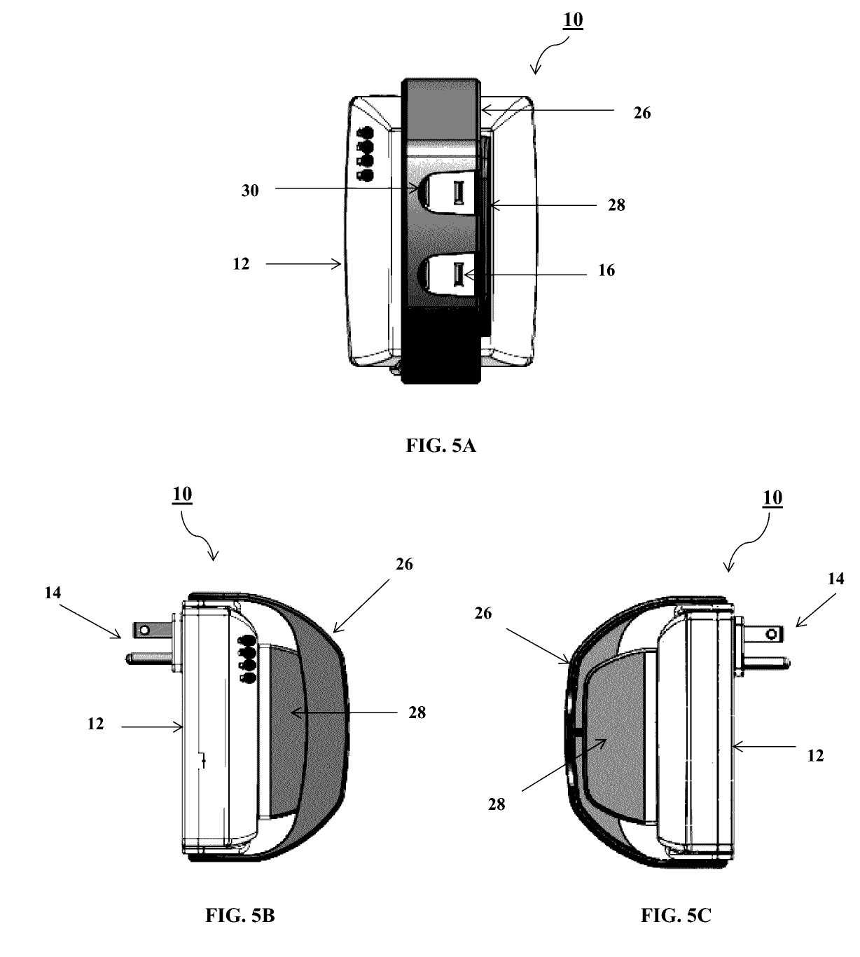

In another aspect of the invention, the lockable smart plug 10 includes a locking band and a wall divider as an apparatus that prevents a member that is inserted into at least one electrical receptacle 16 from being removed. For example, as shown in FIGS. 5A-5C, the locking band 26 and wall divider 28 are designed to securely lock any remote electronic devices plugged into the electrical receptacle(s) 16. In one embodiment, the locking band 26 may include a single member that is configured and dimensioned to extend over each of the electrical receptacle(s) 16 and operatively attach to each end of the housing unit 12, as depicted in FIGS. 5A-5C. In this aspect, the locking band 26 should be dimensioned such that the width of the locking band 26 is at least equal to the width of the electrical receptacle(s) 16.

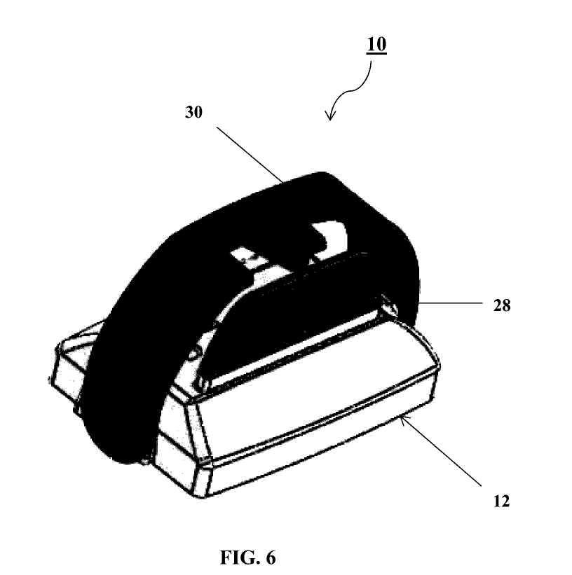

Like the cover 18, the locking band 26 may include at least one opening that is dimensioned to allow the electrical cord of the remote electronic device to egress the lockable smart plug 10 but to not allow the electrical plug of the remote electronic device to be removed. For example, as shown in FIG. 6, the locking band 26 may include at least one U-shaped opening 30 that is closed off on all but one side to allow the electrical cord of the remote electronic device to horizontally slide into the opening 30. The size and shape of the opening 30 may be configured and dimensioned as desired; however, the dimensions of the opening 30 should be configured and dimensioned such that the plug of the remote electronic device is prevented from passing through the opening 30 after the locking band 26 has been secured, although the electrical cord of the remote electronic device is allowed to egress from the smart plug 10. The opening 30 may vary as desired, and may be configured and dimensioned based on the type of plug with which it is intended to be used.

In one embodiment, the locking band 26 includes at least one opening 30 for each electrical receptacle 16. For example, the locking band 26 includes an opening 30 that allows a plug to access each electrical receptacle 16. In another embodiment, one or more openings 30 may be positioned above each electrical receptacle 16.

The locking band 26 may be secured to the housing unit 12 by any means known to those skilled in the art. For example, the locking band 26 may be secured to the housing unit 12 with one or more screws. In another embodiment, the locking band 26 may be secured to the housing unit 12 by way of an adhesive.

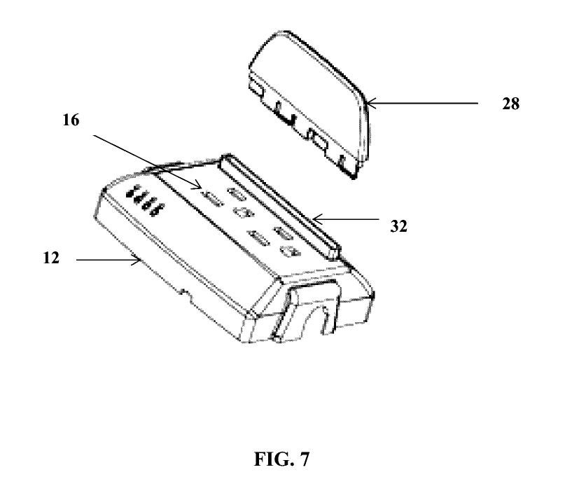

In this embodiment, when a locking band 26 is used, the wall divider 28 is positioned adjacent to the opening(s) 30 of the locking band 26. For example, the wall divider 28 may be operatively secured to the housing unit 12 on the side of the locking band 26 having the opening so as to prevent the electrical plug of the remote electronic device from being removed (e.g., from sliding out). That is, the wall divider 28 is positioned adjacent to the locking band 26 so as to enclose the U-shaped opening 30. In this regard, the wall divider 28 should be dimensioned such that the length of the wall divider 28 is at least equal to or greater than the length of the opening(s) 30 on the locking band 26. The wall divider 28 may be secured to the housing unit 12 by any means known to one of ordinary skill in the art. For instance, as shown in FIG. 7, the housing unit 12 may include a groove or slot 32 that is configured for insertion of the wall divider 28. In another embodiment, the wall divider 28 may be secured to the housing unit 12 by way of one or more screws or an adhesive.

The wall divider 28 may be secured to the housing unit 12 prior to attachment of the locking band 26. For instance, the wall divider 28 may be inserted into a slot or groove 32 on the housing unit 12 before the locking band 26 is attached to the housing unit 12. In this regard, a member may be inserted into at least one electrical receptacle 16 after insertion of the wall divider 28 but prior to attachment of the locking band 26. In another embodiment, the wall divider 28 may be secured to the housing unit 12 after a member is inserted into at least one electrical receptacle 16 and attachment of the locking band 26.

The lockable smart plug 10 further includes a locking mechanism 22 that is configured to lock the cover 18 in place over the electrical receptacle(s) 16 when a remote electronic device is plugged therein. One embodiment of the present invention includes any type of locking mechanism that is operable to securely lock the cover 18 to the housing unit 12 such as to prevent unauthorized users from tampering with or gaining access to the plug of the remote electronic device. For example, in one embodiment, the locking mechanism 22 includes a standard tubular cam-locking mechanism and a tubular key. In another embodiment, the locking mechanism 22 includes an electromagnetic lock. In still another embodiment, the locking mechanism 22 includes a pad lock or a dead bolt lock.

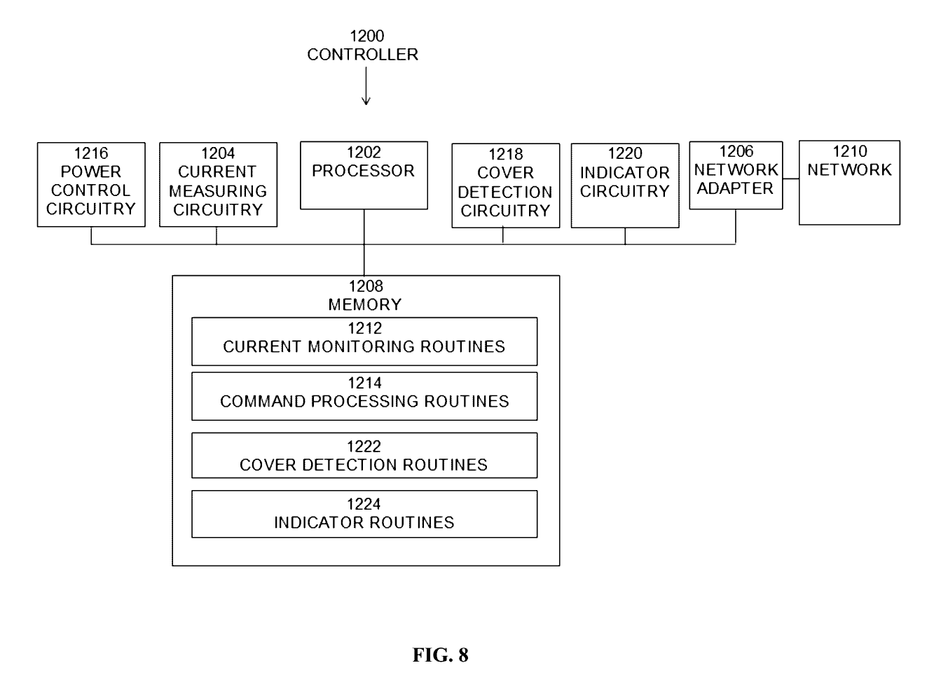

The lockable smart plug 10 further includes an internal controller. An exemplary block diagram of a controller 1200, in which processes involved in the embodiments described herein may be implemented, is shown in FIG. 8. Controller 1200 is typically a programmed and general-purpose processing system, such as an embedded processor, system on a chip, or microcontroller. Controller 1200 may include one or more processors (CPUs) 1202, current measuring circuitry 1204, power control circuitry 1216, cover detection circuitry 1218, indicator circuitry 1220, network adapter 1206, and memory 1208. In one embodiment, CPU 1202 executes program instructions in order to carry out the functions of the present invention. Network adapter 1206 interfaces controller 1200 with a network 1210. Network 1210 may be any public or proprietary LAN or WAN, including, but not limited to the Internet, Wi-Fi, and Bluetooth.

Memory 1208 stores program instructions that are executed by, and data that are used and processed by, CPU 1202 to perform the functions of controller 1200. Memory 1208 may include, for example, electronic memory devices, such as random-access memory (RAM), read-only memory (ROM), programmable read-only memory (PROM), electrically erasable programmable read-only memory (EEPROM), flash memory, etc., and electro-mechanical memory, such as magnetic disk drives, tape drives, optical disk drives, etc., which may use an integrated drive electronics (IDE) interface, or a variation or enhancement thereof, such as enhanced IDE (EIDE) or ultra-direct memory access (UDMA), or a small computer system interface (SCSI) based interface, or a variation or enhancement thereof, such as fast-SCSI, wide-SCSI, fast and wide-SCSI, etc., or Serial Advanced Technology Attachment (SATA), or a variation or enhancement thereof, or a fiber channel-arbitrated loop (FC-AL) interface.

The contents of memory 1208 may vary depending upon the function that controller 1200 is programmed to perform. In the example shown in FIG. 8, exemplary memory contents are shown representing routines and data for embodiments of the processes described herein. However, one of skill in the art would recognize that these routines, along with the memory contents related to those routines, may not be included on one system or device, but rather may be distributed among a plurality of systems or devices, based on well-known engineering considerations. The present invention contemplates any and all such arrangements.

The controller 1200, which includes power control circuitry 1216, provides the capability to independently control and monitor the power supplied by the lockable smart plug 10 to each electrical receptacle 16, and subsequently each electronic remote device plugged therein. In this aspect, memory 1208 may include command processing routines 1214. The controller 1200 can be operatively communicated with over an Internet Protocol (IP) connection using wireless technology (Wi-Fi or Bluetooth). The controller 1200 implements a REST API containing three commands that match the HTTP Verbs: GET, PUT and DELETE. The GET verb tells the controller 1200 to return the current status for the controller 1200 and one or more egress ports. The PUT verb tells the controller 1200 to turn on a specific egress port and optionally includes the total number of seconds the power may be left on. The connection may be secured in any number of ways, including by using standard HTTP schemas for securing communication including, but not limited to, SSL (Secure Socket Layer). SSL may be used in combination with signed requests and/or user/password authentication, and/or third party certificates and verification.

The DELETE command tells the controller 1200 to turn off a specific egress port. For example, a user on a computing device (computer, smart phone, tablet, etc.) may manually authorize the use of the remove device by selecting a virtual representation of the lockable smart plug 10 on their computing device and, that in turn sends a signal to the controller 1200 of the lockable smart plug 10 via Internet Protocol that, in turn allows power to the remote device via its assigned power receptacle. In another example, a remote system may include a schedule of times to turn on and off the remote device. The remote system will send control signals to the lockable smart plug 10 at the appropriate times. Another advantage of one embodiment of the present invention is that the command to power on one egress power receptacle on the lockable smart plug 10 can be appended with a total authorized time in seconds. The lockable smart plug 10 will turn on power to the remote device and begin to count the seconds that have expired since turning the unit on. Once the seconds remaining have expired, the lockable smart plug 10 will automatically turn power off to the specified remote device even if it did not receive the explicit command to shut off.

In this aspect, the present invention is advantageous in that multiple electrical receptacles 16 on a single smart plug 10 can be independently controlled and monitored. This, in turn, allows multiple remote electronic devices to be controlled. For example, a user may allow access to one remote electronic device for a desired amount of time, while allowing access to a different remote electronic device for a different desired amount of time. In this case, only a single lockable smart plug 10 is required. In other embodiments, the amount of electricity, e.g., current, provided to each electrical receptacle 16 may be varied independently.

In another embodiment, controller 1200 includes current measuring or metrology circuitry 1204. The current measuring circuitry 1204 may include a power/current measuring device positioned within the housing unit 12 that monitors a physical variable. In this aspect, memory 1208 may include current monitoring routines 1212. For example, in one embodiment, the measuring device monitors the electric current (amperage) flowing from the lockable smart plug 10 to the remote electronic device. The measuring device may include a processor, such as processor 1202 depicted in FIG. 8, that is operatively connected to the electrical receptacle(s) 16 to monitor the usage of (or the electric current flowing from) the electrical receptacle(s) 16. By monitoring the electric current, the usage time of the remote electronic device can be determined as well as a standard “power fingerprint” which can be used to determine if the remote device has been altered or changed.

A power finger print, as recognized by those skilled in the art, includes a method whereby the identity of the remote electronic device is determined based on the power consumption over a predetermined period of time. Because the amount of power that a device consumes is unique, it can be used to identify a particular device. For instance, a Sony PlayStation 4 consumes a different amount of power when it is running than a Sony PlayStation 3, or a Microsoft Xbox One. Thus, another advantage of the smart plug described herein is that it is operable to determine when a remote device is changed. Yet another advantage is that the smart plug of the present invention is able to determine the specific type (e.g., manufacturer and model) of equipment based on the power fingerprint over a period of time.

Various measuring devices for acquiring physical data are contemplated. In one embodiment, the measuring device includes an ammeter that measures the flow of electric current. In another embodiment, the measuring device includes a voltmeter that measures the supplied voltage to the remote electronic device. In still another embodiment, the measuring device includes the ability to collect and report on the remote device's Power Factor (the ratio of real power to the load of the circuit).

The smart plug 10 in one embodiment of the present invention also includes a method for detecting when the cover 18 is opened, even if the lockable smart plug 10 is powered off In this aspect, the controller 1200 includes cover detection circuitry 1218 to detect when the cover 18 is opened. The memory 1208 may include cover detection routines 1222. For example, in one embodiment, an energy storage device, such as a capacitor, is used to track the state of the cover 18. The capacitor may be configured and dimensioned such that it fits within the housing unit 12. The capacitor may be configured to track the locked state of the cover 18 of the lockable smart plug 10 even when the smart plug 10 is powered down. For example, if the lockable smart plug 10 is unplugged from source power and the cover 18 is opened, the capacitor will discharge, and when the lockable smart plug 10 regains power, it can notify users if the locking mechanism 22 of the smart plug 10 was opened when the smart plug 10 is offline. In another embodiment of the cover monitoring, the present invention includes a physical switch that is triggered when the cover is opened. The switch can only be reset by the lockable smart plug controller when it receives an electrical signal.

Further, the lockable smart plug 10 according to one embodiment of the present invention may include indicia such as one or more LEDs. In this aspect, the controller 1200 includes indicator circuitry 1220. For example, the memory 1208 may include indicator routines 1224. In one embodiment, the one or more indicia may indicate when the smart plug 10 is operatively connected to a power source, e.g., it has power. In another embodiment, the LED may indicate that the lockable smart plug 10 is connected to the wireless (Wi-Fi or Bluetooth) network. In yet another embodiment, the LED may indicate that the lockable smart plug 10 is securely communicating with a remote system over the IP connection. In another embodiment, the smart plug 10 includes a speaker 24 located on the housing unit 12. In this aspect, the speaker 24 makes an audible alert to the user that the power of the remote electronic device is going to be switched off For example, notifications can be made intermittently, for example, with 5 minutes remaining, again with 1 minute remaining, and continuing every 10 seconds until the power is turned off. In yet another embodiment, the smart plug 10 includes a display screen to allow a user to input data or scroll through previous data.

Notwithstanding that the numerical ranges and parameters setting forth the broad scope of the invention are approximations, the numerical values set forth in the specific examples are reported as precisely as possible. Any numerical value, however, inherently contain certain errors necessarily resulting from the standard deviation found in their respective testing measurements. Furthermore, when numerical ranges of varying scope are set forth herein, it is contemplated that any combination of these values inclusive of the recited values may be used.

The invention described and claimed herein is not to be limited in scope by the specific embodiments herein disclosed. Any equivalent embodiments are intended to be within the scope of this invention. Indeed, various modifications of the invention in addition to those shown and described herein will become apparent to those skilled in the art from the foregoing description. Such modifications are also intended to fall within the scope of the appended claims. All patents and patent applications cited in the foregoing text are expressly incorporate herein by reference in their entirety.

Although various embodiments are described herein, they are not intended to be limited to separate use. For instance, aspects of one embodiment may be combined with aspects of another embodiment, and vice versa.

What is claimed is:

1. A smart plug, comprising:
a housing unit;
at least one electrical contact on a rear surface of the housing unit providing ingress AC power;
at least one electrical receptacle on a surface opposite that of the electrical contact providing egress AC power;
a cover configured to close over the at least one electrical receptacle;
a locking mechanism configured to secure the cover to the housing unit;
a measuring device configured to monitor usage of the at least one egress electrical receptacle; and
a controller configured to communicate a status of the smart plug using Internet Protocol over a wireless (Wi-Fi or Bluetooth) connection.

2. The smart plug of claim 1, wherein the cover comprises at least one opening adapted to allow an electrical cord to egress the smart plug.

3. The smart plug of claim 1, further comprising a speaker located on the housing unit.

4. The smart plug of claim 1, wherein the locking mechanism comprises a cam lock or an electromagnetic lock.

5. The smart plug of claim 1, wherein the measuring device is configured to monitor the electric current associated with the at least one electrical receptacle.

6. The smart plug of claim 1, wherein the smart plug comprises two independently controlled electrical receptacles.

7. The smart plug of claim 1, wherein the smart plug is wireless (Wi-Fi or Bluetooth) enabled.

8. The smart plug of claim 1, wherein the controller is operatively connected to the housing unit to independently vary the current to each of the electrical receptacles.

9. A wireless (Wi-Fi or Bluetooth) enabled smart plug for monitoring usage and controlling operation of a remote electronic device plugged therein, comprising:
a housing unit;
at least one electrical contact on a rear surface of the housing unit;
at least one electrical receptacle on the surface opposite that of the electrical contact;
a cover configured to close over the at least one electrical receptacle;
a locking mechanism configured to secure the cover to the housing unit;
a measuring device configured to monitor usage of the at least one electrical receptacle; and
a controller configured to selectively control the on/off condition of the power to the at least one electrical receptacle and subsequently the remote electronic device plugged therein.

10. The smart plug of claim 9, wherein the measuring device is an ammeter.

11. The smart plug of claim 9, wherein the cover comprises dual members connected to opposing walls of the housing unit via a hinge.

12. The smart plug of claim 9, wherein the locking mechanism comprises a cam lock or an electromagnetic lock.

13. A smart plug, comprising:
a housing unit;
at least one electrical contact on a first surface of the housing unit;
at least one electrical receptacle on a second surface of the housing unit;
a locking band configured to extend over the at least one electrical receptacle and to operatively attach to each end of the housing unit, wherein the locking band comprises at least one U-shaped opening;
a wall divider positioned adjacent to the locking band and configured to enclose the at least one U-shaped opening;
a processor operatively connected to the at least one electrical receptacle to monitor the usage of the at least one electrical receptacle; and
a controller configured to selectively control the power status of the at least one electrical receptacle.

14. The smart plug of claim 13, wherein the at least one U-shaped opening is positioned over the at least one electrical receptacle.

15. The smart plug of claim 13, wherein the smart plug comprises two or more electrical receptacles.

16. The smart plug of claim 15, wherein the processor is operatively connected to the two or more electrical receptacles to monitor the usage of the two or more receptacles.

17. The smart plug of claim 13, wherein the smart plug is wireless (Wi-Fi or Bluetooth) enabled.

18. The smart plug of claim 13, wherein the housing unit further comprises a slot configured for insertion of the wall divider.
